(19) United States
(12) Patent Application Publication
(10) Pub. No.: US 2010/0087032 A1
(43) Pub. Date: Apr. 8, 2010

(54) METHOD FOR PATTERNING OF ORGANIC FILM

(75) Inventors: Tatsuya Yoshizawa, Tsurugashima-shi (JP); Takuya Hatakeyama, Tsurugashima-shi (JP); Kenichi Nagayama, Tsurugashima-shi (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION, Meguro-ku, Tokyo (JP)

(21) Appl. No.: 12/531,196

(22) PCT Filed: Mar. 13, 2007
(86) PCT No.: PCT/JP2007/054913

§ 371 Date: Nov. 5, 2009

(51) Int. Cl. H01L 51/40

(52) U.S. Cl. 438/99; 257/E51.027

(57) ABSTRACT

A main subject is to provide a novel method for patterning of organic film which is suitable for manufacturing various organic devices.

In a method for patterning of an organic film formed at a prescribed region, an organic covering layer forming step where an organic covering layer which includes a metal complex is formed on the organic film at a portion which corresponds to a portion where the organic film should be remained after patterning, and a plasma etching step where the organic film which is located at the portion of being not covered with the organic covering layer is etched out by irradiating the organic film with a plasma from above the organic covering layer after the organic covering layer forming step, are included.

### TECHNICAL FIELD

This invention relates to a method for patterning of organic film.

### BACKGROUNDS ARTS

In many case of manufacturing an organic device such as an organic EL element, an organic transistor, and an organic solar cell, a step of patterning one or more of various kinds of organic film would be an essential step.

For a concrete example, in the case of manufacturing an organic EL element, it is known that a polymeric organic functional layer (i.e., organic film) is provided in order to improve surface condition of a first electrode which is formed on a substrate. As the method for preparing the polymeric organic functional layer on the substrate, a wet method (spin coating method, spray coating method, or ink-jet method) has been generally used. The polymeric organic functional layer is also useful for a measure of preventing leak. Further, since the vacuum deposition is not adopted in the wet method, the wet method is useful even when manufacturing a large size display.

In order to drive the organic EL element at last, it is naturally required to give the first electrode an electrical connection with an external circuit by exposing a predetermined portion of the first electrode. Thus, it is necessary to pattern the polymeric organic functional layer formed on the first electrode. Although it will be possible to pattern the polymeric organic functional layer at the step of forming the polymeric organic functional layer on the first electrode, such a patterning is not practical when the wet method is adapted for preparing the polymeric organic functional layer. As the practical way, therefore, a polymeric organic functional layer is initially formed on the whole surface of the first electrode, and then the thus formed polymeric organic functional layer is patterned by removing the prescribed part of the polymeric organic functional layer by dint of the plasma etching.

Although the above-mentioned concrete example is related to the patterning of the polymeric organic functional layer which is formed on the first electrode on the manufacturing of the organic EL element, the patterning step of organic film in condition of a layered structure which utilizes the plasma etching is frequently performed on the productions of various organic devices.

Under such current circumstances, patterning methods for the organic film by etching are disclosed in the following patent literatures 1-2.

Concretely, the patent litereture 1 discloses a patterning method where a second electrode is formed on the organic film, and then the organic film is patterned by functioning the second electrode as a mask.

The patent literature 2 discloses a patterning method where the organic film is patterned by using a metal mask.
Patent Literature 1: JP 2004-006278 A
Patent Literature 2: JP 2003-332073 A
Patent Literature 3: WO2004/110105 A1

### DISCLOSURE OF THE INVENTION

### Problem to be Solved by the Invention

However, regarding the method disclosed in the patent literature 1, namely, the method where the etching is performed using as a mask the second electrode formed on the organic film, the edges of the second electrode which functions as the mask receive damages by the plasma. Further, even for the organic film which locates under the second electrode, there is a possibility that the organic film receives similar damage because the plasma may pass into the organic film through the edges of the second electrode. When the concerned organic film is an organic luminescent layer, there is also a possibility that the non-luminous part is produced by the damage due to the plasma.

Regarding the method disclosed in the patent literature 2, namely, the method where the etching is performed using a metal mask, because a clearance is formed between the organic film to be etched and the metal mask, the plasma may irrupt from and into the clearance. As a result, the organic film may receive damages like the case of the above-mentioned patent literature 1, and thus, there is a possibility that malfunctions such as abnormal luminecence, rising voltage, etc., are caused.

The present invention is contrived by concerning the above-mentioned problems, and it's a main subject is to provide a novel method for patterning of organic film which is suitable for manufacturing various organic devices.

### Means for Solving the Problem

The invention described in claim 1 is a method for patterning of an organic film formed at a prescribed region, which comprises an organic covering layer forming step where an organic covering layer which includes a metal complex is formed on the organic film at a portion which corresponds to a portion where the organic film should be remained after patterning, and a plasma etching step where the organic film which is located at the portion of being not covered with the organic covering layer is etched out by irradiating the organic film with a plasma from above the organic covering layer after the organic covering layer forming step.

### BRIEF DESCRIPTION OF THE DRAWINGS

FIG. 1 is a process drawing which briefly illustrates the method for patterning according to the present invention.

FIG. 2 is diagrams which illustrate steps of manufacturing an organic EL device.

FIG. 3 is diagrams which illustrate steps of manufacturing an organic EL device.

### EXPLANATION OF NUMERALS

10, 21, 31 Substrate

11 Organic film

12, 26, 36 Organic covering layer

22, 32 First electrode

23, 33 Polymeric organic functional layer

24, 34 Organic EL layer

25, 35 Second layer

37 Insulation film

38 Third electrode

39 Protection film

### BEST MODE FOR CARRYING OUT THE INVENTION

Hereinafter, the method for patterning the organic film according to the present invention will be explained concretely with referring to the drawings.

(1) Principal of the Method for Patterning the Organic Film According to the Present Invention.

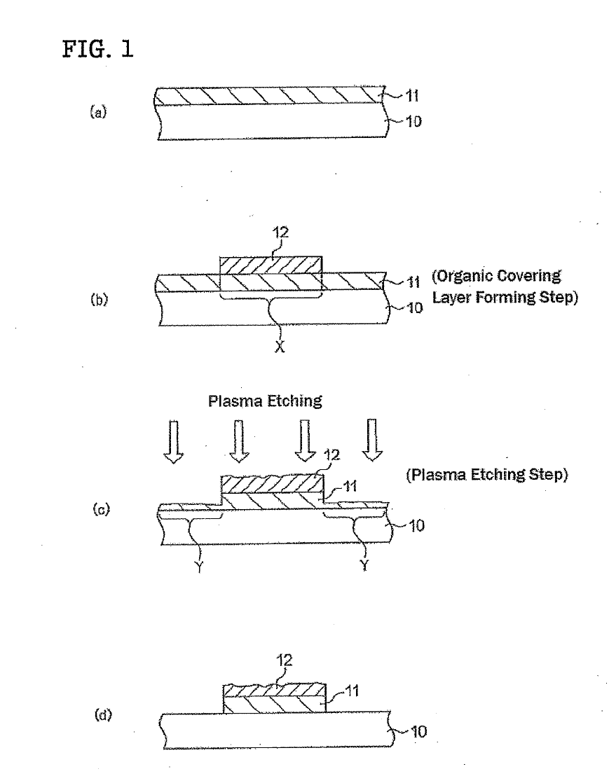

FIG. 1 is a process drawing which briefly illustrates the method for patterning according to the present invention.

FIG. 1(a) is a diagram which shows an object to be patterned by the patterning method according to the present invention.

As illustrated in this figure, the patterning method according to the present invention can be suitably used when patterning an organic film 11 formed onto a substrate 10 into a prescribed shape.

Incidentally, although FIG. 1(a) shows a condition that only the organic film 11 is formed on the substrate 10, the object to be patterned by the patterning method according to the present invention is not limited to such a condition.

For example, the article onto which the organic film is formed is not limited to the substrate 10 shown in this figure, but it may be a three-dimensional structure. Namely, the patterning method according to the present invention can be applied broadly and variously when patterning an organic film which is formed on a certain object into a prescribed pattern.

As for the substrate 10, glass substrates, silicon oxide substrates, and various resin substrates, etc., can be exemplified. Further, such a substrate may be a layered substrate where various thin layers are stacked.

With respect to the kind of the organic membrane 11 which is treated with the plasma etching in accordance with the patterning method of the present invention, there is no particular limitation, similarly. It can be selected as appropriate in accordance with the kind of a final product to be obtained by the patterning method.

As for the concrete examples of the organic membrane 11 to be treated with the plasma etching, when the final product is an organic EL element, an polymeric organic functional layer which is formed onto a first electrode in order to secure smoothness of the surface of the first electrode, and an electron hole transporting layer, a luminescent layer, an electron injection layer or the like, which are formed on or over the polymeric organic functional layer, can be exemplified.

On the other hand, when the final product is an organic semi-conductor, gate insulation film material, organic semi-conductor layer, etc., can be exemplified. Further, when the final product is an organic solar cell, a polymeric organic functional layer, etc., can be exemplified.

FIG. 1(b) is a diagram which illustrates the organic covering film forming step of the patterning method according to the present invention.

As shown in this figure, in the patterning method according to the present invention, the organic covering film forming step is performed in order to form an organic covering layer 12 which includes a metal complex on the organic film at a portion X which corresponds to a portion where the organic film should be remained after patterning.

By providing this step, the organic covering layer 12 which includes a metal complex can function as a mask at the plasma etching step which is performed after this step, and thus the organic film 11 of being located at the portion which corresponds to the portion where the organic covering layer 12 was formed can be remained, and the organic film 11 of being located at portions which correspond to portions other than the above-mentioned organic covering layer formed portion can be removed.

Means for forming the organic covering layer 12 which functions as a mask is not particularly limited to a certain specific means, and it can be properly selected from all of means known in the art. Since the organic covering layer 12 can comprise the same organic material that the organic film 11 which is removed by the etching treatment is comprised, it is possible to use the same means that the organic layer 11 is formed for forming the organic covering layer 12. When the organic film 11 and the organic covering layer 12 are formed with the same means, the manufacturing steps can be simplified.

As for means for forming the organic covering layer 12, and for forming the organic film 11, vapor deposition, spin coating, splaying, ink-jet printing, etc., can be exemplified. Further, the both articles (the organic covering layer 12, and the organic film 11) may be formed by appropriately combining one of these means with another of these means.

Further, as clear from FIG. 1(b), because no clearance exists between the organic film 11 to be etched and the organic covering layer which functions as a mask, it is possible to evade the occurrence of damage due to the plasma at the portion X which should be remained, the damage being caused when the plasma irrupts from and into such a clearance.

Although the reason why the organic covering layer 12 functions as the mask has not been clearly elucidated yet, it is probably because the metal complex included in the organic covering layer 12 prevent plasma invasion. Incidentally, the organic covering layer 12 in the method of the present invention itself is not entirely escaped from the etching, when the plasma is irradiated. The organic covering layer 12 itself is also etched out gradually. However, because the resistance against the plasma of the organic covering layer 12 is high as compared with that of the organic film 11 which is the object to be etched out, the eching of the organic film 11 can be completed before the the organic covering layer 12 is entirely etched out. Thus, the organic covering layer 12 can function as the mask.

As for the metal complex included in such an organic covering layer 12, Al complexes, Ir complexes, Eu complexes, Pt complexes, Cu complexes, Zn complexes, Ru complexes, Os complexes, Au complexes, etc., are exemplified. More concretely, for example, as for Al complex, Alq₃ (tris(8-hydroxypuinoline)aluminum) can be enumerated. As for Ir complex, Ir(ppy)₃ (Tris[2-(2-pyridinyl)phenyl-C,N]-iridium) can be enumerated. As for Eu complex, Eu (DPM) (Tris(dibenzoylmethane)mono(4,7-diphenyl phenathroline)europium (III)) can be enumerated.

As for Pt complex, PtOEP (2,3,7,8,12,13,17,18-Octaethyl-21H,23H-porphine, platinum (II)) can be enumerated. AS for Cu complex, CuPC (Copper (II) phthalocyanine) can be enumerated. As for Zn complex, Znq₂ (Bis(8-hydroxy quinolato)zinc) can be enumerated.

Further, as for Ru complex, Ru(phen)CL(1,10-Phenanthrolene Ruthenium Chloride) can be enumerated. As for Os complex, Os(DPS) (cis-1,2-bis(diphenyl phosphino)ethylene Osmium (II)) can be enumerated.

Incidentally, the “metal complex” used herein denotes a compound which has a structure consisting of metal atom(s) sited at the centre, and ligands which surround and connected to the metal atom(s).

As for the material of the organic covering layer (balk resin), there is no particular limitation, and any high molecular weight material or low molecular weight material of various kinds can be used on an appropriate selection. For instance, acrylic type resins and epoxy type resins can be enumerated.

Further, the amount of the metal complex included in the organic covering layer 12 is not particularly limited as far as the organic covering layer 12 can function as the mask.

In addition, as for the thickness of the organic covering layer 12, there is no particular limitation as far as the organic covering layer 12 sustains at least a thickness capable of functioning as the mask up until the time when the etching of the organic film 11 to be etched out is completed, as described above. Thus, the thickness of the organic covering layer 12 can be varied appropriately depending upon the kind, thickness, etc., of the organic film 11 to be etched out. For instance, when the polymeric organic functional layer formed on the first electrode is etched out on the manufacturing of the above-mentioned organic EL element, a thickness in the range of about 1-1000 nm is adequate.

In the patterning method according to the present invention, it is possible to determine the thickness of the organic covering layer 12 in consideration of the etching rates (amounts of being etched out per a unit time) both of the organic film 1 as the target of the etching treatment and the organic covering layer 12 which functions as the mask on the etching treatment. Namely, as described above, in the present invention, since it is enough that the organic covering layer 12 can exist as the mask up until the time when the organic film 11 is removed by etching, for instance, assuming the etching rate of the organic film 11 is 1 and the etching rate of the organic covering layer 12 is 1/10, it is enough that the thickness of the organic covering layer 12 is not less than 1/10 of the thickness of the organic film 11. Similarly, assuming the etching rate of the organic film 11 is 1 and the etching rate of the organic covering layer 12 is ⅓, it is enough that the thickness of the organic covering layer 12 is not less than ⅓ of the thickness of the organic film 11.

FIG. 1(C) is a diagram which illustrates the plasma etching step of the patterning method according to the present invention.

FIG. 1(D) is a diagram which illustrates the state that the patterning method according to the present invention is accomplished.

As described above, in the patterning method according to the present invention, after the organic covering layer forming step, the plasma etching is performed by irradiating the plasma from above the organic covering layer 12 so that the organic film 11 of being located at portions Y which are not covered with the organic covering layer 12 is removed.

As shown in FIG. 1(C), during this step, the organic film 11 located at the portions Y which are not covered with the organic covering layer 12 is selectively and gradually removed off by etching (simultaneously, as shown in this figure, the organic covering layer 12 are also etched out slightly.). At the end, the organic film can be patterned to a desired shape as shown in FIG. 1(d).

As for the etching condition in the method according to the present invention, there is no particular limitation, and the condition can be chosen appropriately. Concretely, for instance, it is possible to generate an oxygen plasma by using a mixture gas in which a rare gas (Ar, Kr, etc.) is added to oxygen, and applying RF discharge thereto. Alternatively, it is possible to generate the plasma by using a single gas of oxygen only and applying anode coupling or cathode coupling. Further, it is also possible to use a single gas of a rare gas only.

As shown in FIG. 1(d), even after the plasma etching step is completed, the organic covering layer is still remained. However, since the organic covering layer is very thin film and is made of an organic material, it is considered that no particularly adverse problem would be caused by the remaining organic covering layer (it is also possible to remove it, if the removal of it is required.) On the contrary, when an another film (for instance, a protective layer in the case of manufacturing an organic EL element) is layered on the patterned organic film 11, it can be considered that the organic covering layer functions as a buffer layer for the another layer.

(2) Application Example 1 of the Patterning Method According to the Present Invention

Now, the patterning method according to the present invention will be explained more concretely by exemplifying an example where the patterning method is applied to the manufacturing steps of an organic EL element.

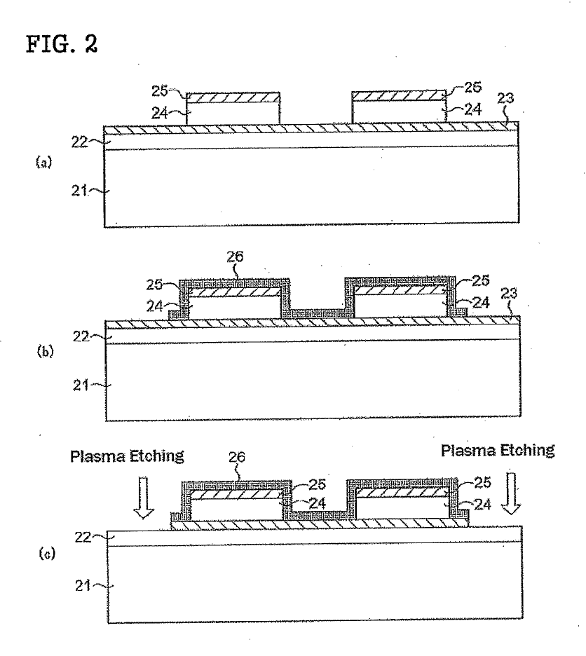

FIG. 2 is diagrams which illustrate steps of manufacturing an organic EL device.

As shown in FIG. 2(a), a first electrode 22 is formed on a substrate 21 by photolithographic patterning method or the like, and further a polymeric organic functional layer 23 is formed on the first electrode 22 by a wet method such as spin-coating method, spraying method, etc.

As the substrate 21, any material which has insulation property at least the surface thereof can be used. For instance, it may be an insulation material such as glass, surface-oxidized silicon wafer, etc. Further, it may show flexibility, and/or transparency.

The first electrode 22 can be made of a low resistance material such as various metals (involving alloys), etc., and it may show transparency.

The polymeric organic functional layer 23 can be made of a conductive polymeric material, typically represented by polyaniline, polyacetylene, polypyrrole, polythiophene, etc. The thickness of this layer is preferably in the range of 1-1000 nm, more desirably, in the range of 10-100 nm.

Further, as shown in FIG. 2(a), an organic EL layer 24 is formed on the polymeric organic functional layer 23, and a second electrode 25 is further formed on the organic EL layer 24.

The organic EL 24 may be of a layered structure which includes various thin layers such as electron hole transporting layer, electron injection layer in addition to a luminescent layer which possesses electroluminescence property. As for the material and the forming method of the organic EL layer 24, there is no particular limitation, and any material and any method known in this art can be used on an appropriate selection.

Similar to the case of the first electrode 22, the second electrode 22 can be made of a low resistance material such as various metals (involving alloys), etc., and it may show transparency. More concretely, it can be formed by heating and vapor-depositing aluminum.

Next, as shown in FIG. 2(b), an organic covering layer 26 is formed on the condition that, at the portions where the polymeric organic functional layer 23 formed on the substrate 21 should be removed by etching (unnecessary portions), the polymeric organic functional layer 23 is still maintained in its exposure state (the organic covering layer forming step).

The explanation of the organic covering layer 26 used in this example will be omitted, because it has been previously described above.

Next, as shown in FIG. 2(c), the plasma is irradiated after the formation of the organic covering layer 26 (the plasma etching step). Thereby, the polymeric organic functional layer 23 located at the portions of being not masked with the organic covering layer 26 is removed by etching, and thus it is possible to expose the first electrode at the portions.

(3) Application Example 2 of the Patterning Method According to the Present Invention

Now, the patterning method according to the present invention will be explained more concretely by exemplifying an example where the patterning method is applied to the manufacturing steps of another organic EL element.

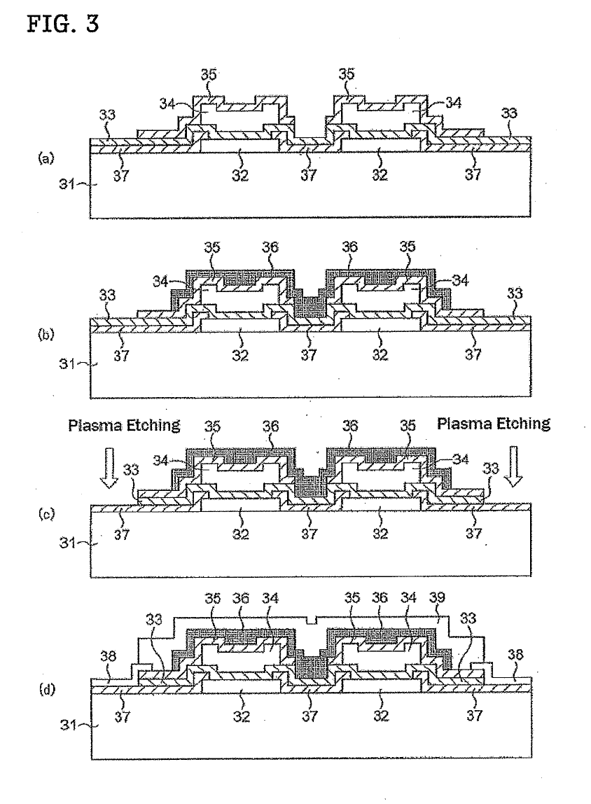

FIG. 3 is diagrams which illustrate steps of manufacturing an organic EL device.

As shown in FIG. 3(a), a first electrode 32 of a patterned shape is formed on a substrate 21 by photolithographic patterning method or the like, and then an insulation film 37 is formed. After the insulation film is formed, a polymeric organic functional layer 33 is formed on the surface of the first electrode 22 by a wet method such as spin-coating method, spraying method, etc.

Then, as shown in FIG. 3(a), an organic EL layer 34 is formed on the polymeric organic functional layer 33, and further an second electrode 35 is formed thereon.

Next, as shown in FIG. 3(b), an organic covering layer 36 is formed on the condition that, at the portions where the polymeric organic functional layer 33 formed on the insulation film 37 should be removed by etching (unnecessary portions), the polymeric organic functional layer 33 is still maintained in its exposure state (the organic covering layer forming step).

Next, as shown in FIG. 3(c), the plasma is irradiated after the formation of the organic covering layer 36 (the plasma etching step). Thereby, the polymeric organic functional layer 33 located at the portions of being not masked with the organic covering layer 36 and the second electrode 35 is removed by etching, and thus it is possible to expose the insulation film 37 at the portions.

Then, as shown in FIG. 3(d), a third electrode 38 is formed so as to cover the exposed insulation film 37.

Further, as shown FIG. 3(d), a protective film 39 may be provided so as to cover the whole of the organic EL element. When the protective film 39 is provided, the organic covering layer 36 can function as a buffer layer on the formation of the protective film 39.

As described above, according to the patterning method of the present invention, it becomes possible to simplify the manufacturing steps dramatically, because the etching is performed using as a substitute for the mask an organic covering layer which is made of the same organic material as the organic film to be etched is made, without using a metal mask or without using as a mask an electrode, a protective film or the like which are used in the methods of the prior arts. Further, it becomes possible to prevent effectively the other portions from receiving damages due to the irradiated plasma, because the organic covering layer which functions as the mask can be formed so as to adhere closely to the organic film to be etched.

Furthermore, the patterning method according to the present invention can be applied to various cases where a certain organic film is subjected to the plasma etching. The method can be used not only for organic devices but also for inorganic devices as far as a certain organic film exists in the structure of the device and the organic film is subjected to the etching treatment. For instance, although the organic EL elements has been illustrated as concrete examples in the above explanation, the explanation, per se, can be applied to the organic solar cell.

1-3. (canceled)

4. A method for patterning of an organic film formed at a prescribed region, which comprises:
an organic covering layer forming step where an organic covering layer which includes a metal complex is formed on the organic film at a portion which corresponds to a portion where the organic film should be remained after patterning, and
a plasma etching step where the organic film which is located at the portion of being not covered with the organic covering layer is etched out by irradiating the organic film with a plasma from above the organic covering layer after the organic covering layer forming step.

5. The method for patterning of an organic film according to claim 4, wherein the metal complex included in the organic covering layer is a metal complex selected from the group consisting of:
Alg₃ (tris(8-hydroxypuinoline)aluminum), Ir(ppy)₃ (Tris[2-(2-pyridinyl)phenyl-C,N]-iridium), Eu(DPM) (Tris(dibenzoylmethane)mono(4,7-diphenyl phenathroline)europium (III)),
PtOEP (2,3,7,8,12,13,17,18-Octaethyl-21H,23H-porphine, platinum (II)), CuPC (Copper (II) phthalocyanine), Znq₂ (Bis(8-hydroxy quinolato)zinc), Ru(phen)CL(1,10-Phenanthrolene Ruthenium Chloride), and Os(DPS) (cis-1,2-bis(diphenyl phosphino)ethylene Osmium (II)).

6. The method for patterning of an organic film according to claim 4, wherein the organic film to be patterned is an organic film which constitutes a part of an organic device.

7. The method for patterning of an organic film according to claim 6, wherein the organic device is a device selected from the group consisting of organic EL devices, organic transistors, and organic solar cells.
